(19) United States
(12) Patent Application Publication
(10) Pub. No.: US 2006/0216415 A1
(43) Pub. Date: Sep. 28, 2006

(54) Vapor aluminide coating gas manifold

(75) Inventors: Walter E. Olson, Vernon, CT (US); Mathew C. Gartland, Trumbull, CT (US)

Correspondence Address: BACHMAN & LAPOINTE, P.C. (P&W), 900 CHAPEL STREET, SUITE 1201, NEW HAVEN, CT, 06510-2802, US

(73) Assignee: UNITED TECHNOLOGIES CORPORATION

(21) Appl. No.: 11/089,989

(22) Filed: Mar. 24, 2005

(51) Int. Cl. B05D 7/22; C23C 16/00

(52) U.S. Cl. 427/237; 427/248.1; 118/715

(57) ABSTRACT

A manifold for use in a process for coating different sized passages in a workpiece is provided. The manifold has an internal chamber, an inlet for receiving a flow of a coating gas, and a flow diverter within the internal chamber for separating the flow of coating gas into a first flow sufficient to coat a full length of surfaces of a first internal passage set having a first cross section dimension and a second flow sufficient to coat a full length of surfaces of a second internal passage set having a second cross section dimension smaller than the first cross section dimension.

### BACKGROUND OF THE INVENTION

(1) Field of the Invention

The present invention relates to an improved process for coating the internal surfaces of workpieces, such as turbine blades and vanes, having internal passageways and to a manifold used in the process.

(2) Prior Art

Aluminide coatings provide protection against oxidation and corrosion degradation to nickel and cobalt based superalloy articles used in gas turbine engines. In general, aluminide coatings are formed by heating a powder mixture containing a source of aluminum, an activator, and an inert buffer or diluent, in the presence of the article to be coated. The article may be located in out-of-contact relation with the powder mixture, hence the process is called a vapor phase process.

When coating internal surfaces of turbine blades and vanes to protect the internal surfaces, a sufficient amount of aluminide coating gas must pass in contact with the surface in order to produce a NiAl diffusion coating of the required thickness and composition. The ability of the coating process to effectively and uniformly coat the internal surfaces is a direct function of the distribution and flow of the aluminum halide carrier gas through the internal passages. Factors making internal coating coverage more difficult are: (1) complex serpentine passages; (2) long distance and/or high aspect ratio (length-to-width/cross section) passages; (3) very narrow passages; and 4) an array of different size passage openings.

One such process involves flowing an aluminum halide gas, such as AlF₃, under pressure through an opening in the root of a workpiece allowing the gas to penetrate all internal passages. Depending upon the design of the workpiece, there usually are multiple openings in the base of the workpiece to allow flow into the various internal passages. The gas is introduced into the blade through a manifold that is sealed to the base of the blade to direct all flow to the internal cavities and prevent leakage to the outside. The ability of the aluminum halide gas to coat long narrow passages, or very winding, long serpentine passages is directly related to the ability of the manifold design to get sufficient gas flow for the full length of the passage. Currently, there is no provision in the manifold design to control the amount of flow that enters each of the openings in the base of the blade root.

### SUMMARY OF THE INVENTION

Accordingly, it is an object of the present invention to provide a manifold which allows the flow of a coating gas to be selectively higher to some locations.

It is a further object of the present invention to provide an improved process for coating internal passageways of a workpiece.

The foregoing objects are attained by the manifold and the process of the present invention.

In accordance with the present invention, a manifold for use in a process for coating different sized passages in a workpiece is provided. The manifold broadly comprises an internal chamber, an inlet for receiving a flow of a coating gas, and means within the internal chamber for separating the flow of coating gas into a first flow sufficient to coat a full length of surfaces of a first internal passage set having a first cross section dimension and a second flow sufficient to coat a full length of surfaces of a second internal passage set having a second cross section dimension smaller than said first cross section dimension.

Further in accordance with the present invention, a process for coating internal passages in a workpiece is provided. The process broadly comprises the steps of providing a source of a coating gas, providing a manifold connected to the source of the coating gas and to the workpiece, and separating the flow of coating gas within the manifold into a first flow sufficient to coat a full length of surfaces of a first internal passage set having a first cross section dimension and a second flow sufficient to coat a full length of surfaces of a second internal passage set having a second cross section dimension smaller than the first cross section dimension.

Other details of the vapor aluminide coating gas manifold of the present invention, as well as other objects and advantages attendant thereto, are set forth in the following detailed description and the accompanying drawing wherein like reference numerals depict like elements.

### BRIEF DESCRIPTION OF THE DRAWINGS

FIG. 1 is a schematic representation of a first embodiment of a system for coating internal passages of a workpiece using a manifold in accordance with the present invention; and

FIG. 2 is a schematic representation of a second embodiment of a system for coating internal passages of a workpiece using a plurality of manifolds.

### DETAILED DESCRIPTION OF THE PREFERRED EMBODIMENT(S)

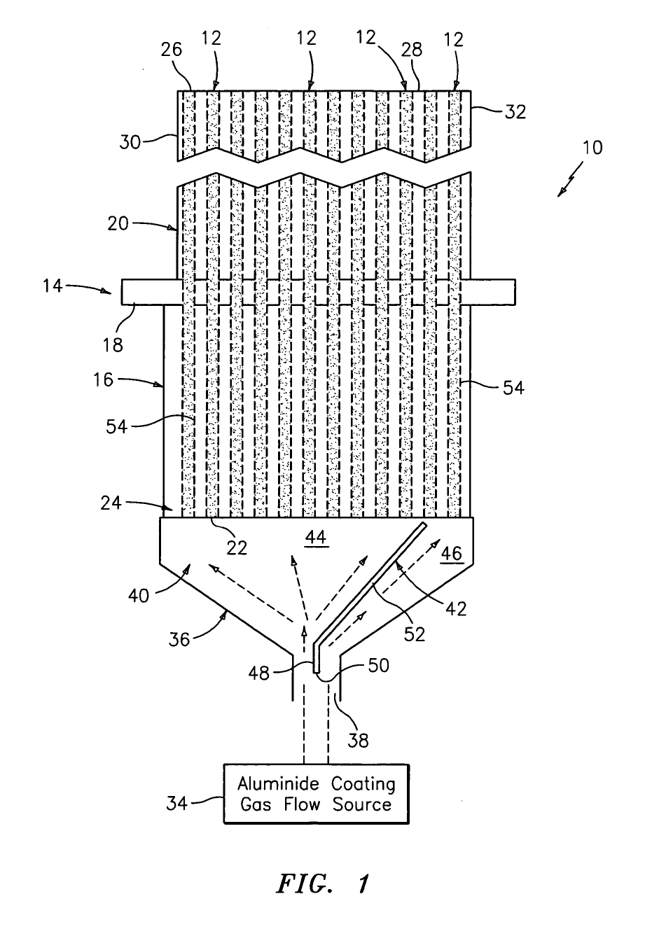

Referring now to FIG. 1, there is shown a system 10 for coating internal passages 12 of a workpiece 14, such as a blade or vane for use in a turbine engine. The workpiece 14 may have a root portion 16, a platform 18, and an airfoil portion 20. A plurality of internal passages 12 may extend from an opening 22 in the base 24 of the workpiece to an outlet cooling hole 26 at a tip end 28 of the airfoil portion 20. While the passages 12 have been shown as being linear passageways, it should be recognized that the passages 12 could be serpentine or otherwise non-linearly shaped. Often cross section dimensions, such as the diameters, of the passages 12 change across the width of the airfoil portion 20. For example, the passage 12 adjacent the leading edge 30 of the airfoil portion 20 may have a relatively large cross section dimension, while the passage 12 adjacent the trailing edge 32 of the airfoil portion 20 may have a relatively small cross section dimension. As a result, the cooling hole 26 adjacent the leading edge 30 may have a cross section dimension which is greater than the cross section dimension of the cooling hole 26 adjacent the trailing edge 32.

The system 10 includes a source 34 of an aluminide coating gas, such as AlF₃ gas. This gas may be generated in a remote location by a reaction of a halide activator (ie. AlF₃, NH₄F.HF, NH₃Cl, AlCl₃ etc.) with an aluminum-rich source metal (ie. CrAl, Co₂Al₅, NiAl, pure Al, etc.) at coating process temperature and fed to the inlet of the manifold by an Ar carrier gas. A typical aluminide coating process is from about 2 to 8 hours at a temperature in the range of 1700-2100° F. Gas flows for internal coating range from 1.0 to 15.0 cfh per part with higher pressures being used for longer or more complex passages.

The system 10 further includes a flow manifold 36 which has an inlet 38 for receiving the aluminide coating gas from the source 34. The inlet 38 may communicate with the source 34 using any suitable means known in the art. The manifold 36 may be attached to the base 24 of the workpiece 12 by any suitable means known in the art. Preferably, the manifold 36 is attached to the base 24 in a way which prevents gas leakage between the manifold 36 and the base 24.

As can be seen from FIG. 1, the manifold 36 has an internal chamber 40 with a flow diverter 42 separating the chamber 40 into a first section 44 and a second section 46. To insure that the smaller cross section dimension passageways are coated to a desired thickness and the desired uniformity, the flow diverter 42 is set to cause a controlled portion of the incoming coating gas to flow into the opening 22 of the smaller cross section dimension passages(s). The actual percentage of flow which may be diverted is a function of the passage size and configuration.

As can be seen from FIG. 1, the flow diverter 42 has a first portion 48 which preferably has a leading edge 50 within the inlet 38 of the manifold 36. The flow diverter 42 also has a second portion 52 which is angled with respect to the first portion 48. The second portion 52 extends to a point very close to or adjacent the outlet of the manifold 36. The flow diverter 42 prevents any flow of the coating gas between the sections 44 and 46.

The flow diverter 42 may be stationary or movable so that the flow of the coating gas may be apportioned as needed. For example, the portion 48 of the flow diverter may be laterally movable within the inlet 38 to apportion the gas flow as needed. Alternatively, the second portion 52 may be movable relative to the first portion 48 to change the relative size of the sections 44 and 46 and hence the amount of coating gas flow to the rearmost passage or passages 12.

The provision of the flow diverter 42 allows a greater flow of coating gas to be directed to difficult to coat passages while still providing sufficient flow to the rest of the openings 22 to allow the formation of an acceptable coating on all internal surfaces 54.

The coating trial results shown in Tables I and II demonstrate the benefits of the manifold design of the present invention. In this trial, a turbine blade with internal passages had the internal passages coated. The turbine blade which was used had a first passage adjacent the leading edge and a cooling hole with a diameter of 0.132 inches, had second through eleventh passages and cooling holes with a diameter of 0.118 inches, and a twelfth passageway, adjacent the trailing edge, and a cooling hole with a diameter of 0.069 inches. Each outlet cooling hole was about 10 inches above the manifold. The trial results shown in Table I are for a system where the manifold did not have a flow diverter in accordance with the present invention. The trial results shown in Table II are for a system wherein the manifold had a flow diverter in accordance with the present invention. As can be seen from this data, hole 12 did not coat at the outer extremity without the diverter.

TABLE I

| Distance | PWA 275 Coating Thickness (mils) | | | | | | |
|---|---|---|---|---|---|---|---|
| above | Without Manifold Diverter | | | | | | |
| the | | | | | | Hole | Hole |
| manifold | Hole 1 | Hole 2 | Hole 5 | Hole 7 | Hole 9 | 11 | 12 |
| 10″ | 1.7 | 1.8 | 1.9 | 1.8 | 1.8 | 1.8 | 0 |
| 8″ | 1.8 | 1.9 | 1.9 | | | 1.8 | 1.1 |
| 5″ | 1.7 | 1.8 | 1.8 | | | 1.8 | 1.3 |
| 0.5″ | 1.6 | 1.8 | 1.7 | 1.7 | | 1.9 | 1.7 |

TABLE II

| Distance | PWA 275 Coating Thickness (mils) | | | | | | |
|---|---|---|---|---|---|---|---|
| above | With Manifold Diverter | | | | | | |
| the | | | | | | Hole | Hole |
| manifold | Hole 1 | Hole 2 | Hole 5 | Hole 7 | Hole 9 | 11 | 12 |
| 10″ | 1.5 | 1.7 | 1.7 | 1.6 | 1.6 | 1.6 | 1.0 |
| 8″ | 1.5 | 1.7 | 1.8 | 1.7 | 1.7 | 1.7 | 1.4 |
| 5″ | 1.6 | 1.7 | 1.8 | 1.7 | 1.7 | 1.8 | 1.5 |
| 0.5″ | 1.6 | 1.6 | 1.5 | 1.6 | 1.5 | 1.5 | 1.7 |

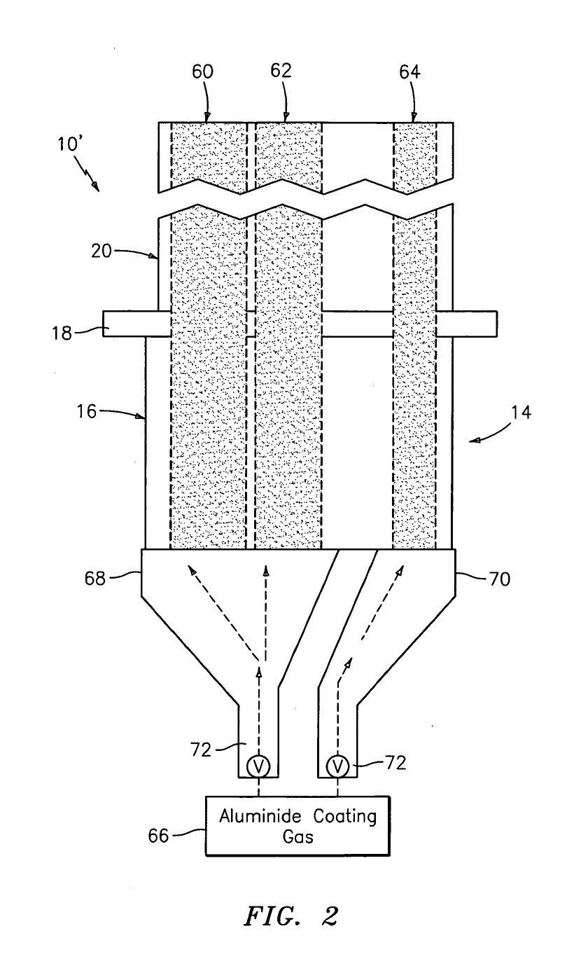

Referring now to FIG. 2, there is shown a second embodiment of a system 10′ for coating internal passages in a workpiece 14. As before, the workpiece 14, such as a blade or vane for use in a turbine engine, may have a root portion 16, a platform 18, and an airfoil portion 20. The workpiece 14 may have one or more leading edge passages 60, one or more midbody passages 62, and one or more trailing edge passages 64. As before, there is a source 66 of a coating gas such as an aluminide coating gas.

As can be seen from FIG. 2, the system 10′ has a first flow manifold 68 and a second flow manifold 70. The first flow manifold 68 provides a first incoming coating gas flow to the inlets of the passages 60 and 62. The second flow manifold 70 provides a second incoming coating gas flow to the passage or passages 64. Suitable means, such as valves, may be provided for controlling the quantity of gas which flows through each of the manifolds 68 and 70. This approach allows each manifold 68 and 70 to flow at a different rate.

While a single coating gas source 66 has been shown in FIG. 2, more than one coating gas source may be used. For example, each of the manifolds 68 and 70 may have its inlet 72 communicating with a separate coating gas source.

If desired, one or more of the manifolds 68 and 70 may be provided with a flow diverter 42 as described hereinabove.

It is apparent that there has been provided in accordance with the present invention a vapor aluminide coating gas manifold which fully satisfies the objects, means, and advantages set forth hereinbefore. While the present invention has been described in the context of specific embodiments thereof, other alternatives, modifications, and variations will become apparent to those skilled in the art having read the foregoing description. Accordingly, it is intended to embrace those alternatives, modifications, and variations as fall within the broad scope of the appended claims.

1. A manifold for use in a process for coating different sized passages in a workpiece comprising:
an internal chamber;
an inlet for receiving a flow of a coating gas; and
means within the internal chamber for separating the flow of coating gas into a first flow sufficient to coat a full length of surfaces of a first internal passage set having a first cross section dimension and a second flow sufficient to coat a full length of surfaces of a second internal passage set having a second cross section dimension smaller than said first cross section dimension.

2. A manifold according to claim 1, wherein said flow separating comprises a flow diverter.

3. A manifold according to claim 2, wherein said flow diverter is stationary within said chamber.

4. A manifold according to claim 2, wherein said flow diverter is movable within said chamber.

5. A manifold according to claim 2, wherein said flow diverter has a first portion which extends into said inlet and a second portion angled relative to said first portion.

6. A manifold according to claim 5, wherein said manifold has an outlet and said second portion extends from said first portion to a point in close proximity to said outlet.

7. A system for coating internal passages of a workpiece comprising:
a source of a coating gas;
a manifold connected to said source of said coating gas and to said workpiece; and
said manifold having an internal chamber, an inlet for receiving a flow of said coating gas, and means within the internal chamber for separating the flow of coating gas into a first flow sufficient to coat a full length of surfaces of a first internal passage set having a first cross section dimension and a second flow sufficient to coat a full length of surfaces of a second internal passage set having a second cross section dimension smaller than said first cross section dimension.

8. A system according to claim 7, wherein said source of said coating gas comprises a source of aluminum halide gas.

9. A system according to claim 7, wherein said source of said coating gas comprises a source of AlF₃.

10. A system according to claim 7, wherein said flow separating comprises a flow diverter.

11. A manifold according to claim 10, wherein said flow diverter is stationary within said chamber.

12. A manifold according to claim 10, wherein said flow diverter is movable within said chamber.

13. A manifold according to claim 10, wherein said flow diverter has a first portion which extends into said inlet and a second portion angled relative to said first portion.

14. A manifold according to claim 13, wherein said manifold has an outlet and said second portion extends from said first portion to a point in close proximity to said outlet.

15. A process for coating internal passages of a turbine engine component, said process comprising the steps of:
providing a source of a coating gas;
providing a manifold connected to said source of said coating gas and to said workpiece; and
separating the flow of coating gas within said manifold into a first flow sufficient to coat a full length of surfaces of a first internal passage set having a first cross section dimension and a second flow sufficient to coat a full length of surfaces of a second internal passage set having a second cross section dimension smaller than said first cross section dimension.

16. A process according to claim 15, further comprising delivering said first flow to an opening of each of a plurality of pages forming said first internal passage set and delivering said second flow to an opening of at least one internal passage forming said second internal passage set.

17. A process according to claim 16, wherein said second flow delivering step comprises delivering said second flow to a plurality of internal passages forming said second internal passage set.

18. A process according to claim 15, wherein said step of providing a source of a coating gas comprises providing a source of aluminum halide gas.

19. A process according to claim 15, wherein said step of providing a source of-a coating gas comprises providing a source of AlF₃.

20. A process according to claim 15, wherein said separating step comprises positioning a flow diverter within said manifold to separate said incoming flow of coating gas into said first and second flows.

21. A process according to claim 20, wherein said positioning step comprises moving said flow diverter within said manifold.

22. A system for coating internal passages of a workpiece comprising:
at least one source of a coating gas;
first manifold means connected to said at least one source of coating gas for delivering a first flow of coating gas to a first set of said internal passages; and
second manifold means connected to said at least one source of coating gas for delivering a second flow of coating gas to a second set of said internal passages.

23. A system according to claim 22, wherein said first manifold means is connected to a first source of said coating gas and said second manifold means is connected to a second source of said coating gas.

24. A system according to claim 22, wherein said first manifold means comprises a first manifold and said second manifold means comprises a second manifold separate from said first manifold.

25. A system according to claim 22, wherein said first manifold means comprises a first section of a chamber and said second manifold means comprises a second section of said chamber separated from said first section.

26. A system according to claim 25, wherein said first and second sections are separated by a flow diverter.

27. A system according to claim 22, wherein said at least one source comprises a source of aluminum halide gas.
